(19) United States
(12) Patent Application Publication
(10) Pub. No.: US 2015/0302903 A1
(43) Pub. Date: Oct. 22, 2015

(54) SYSTEM AND METHOD FOR DEEP COALESCING MEMORY MANAGEMENT IN A PORTABLE COMPUTING DEVICE

(71) Applicant: QUALCOMM INCORPORATED, SAN DIEGO, CA (US)

(72) Inventors: PANKAJ CHAURASIA, SAN DIEGO, CA (US); MOINUL KHAN, SAN DIEGO, CA (US); VINOD CHAMARTY, SAN DIEGO, CA (US); SUBBARAO PALACHARLA, SAN DIEGO, CA (US); DEXTER CHUN, SAN DIEGO, CA (US)

(73) Assignee: QUALCOMM INCORPORATED, SAN DIEGO, CA (US)

(21) Appl. No.: 14/257,980

(22) Filed: Apr. 21, 2014

(51) Int. Cl. G11C 7/10; G06F 12/08

(52) U.S. Cl. CPC G11C 7/1072; G06F 12/0833; G06F 2212/62

(57) ABSTRACT

Various embodiments of methods and systems for deep coalescing memory management (“DCMM”) in a portable computing device (“PCD”) are disclosed. Because multiple active multimedia (“MM”) clients running on the PCD may generate a random stream of mixed read and write requests associated with data stored at non-contiguous addresses in a double data rate (“DDR”) memory component, DCMM solutions triage the requests into dedicated deep coalescing (“DC”) cache buffers, sequentially ordering the requests and/or the DC buffers based on associated addresses for the data in the DDR, to optimize read and write transactions from and to the DDR memory component in blocks of contiguous data addresses.

### DESCRIPTION OF THE RELATED ART

Portable computing devices (“PCDs”) are becoming necessities for people on personal and professional levels. These devices may include cellular telephones, portable digital assistants (“PDAs”), portable game consoles, palmtop computers, and other portable electronic devices.

One aspect of PCDs that is in common with most computing devices is the use of electronic memory components for storing instructions and/or data. Various types of memory components may exist in a PCD, each designated for different purposes. Commonly, random access memory (“RAM”) such as double data rate (“DDR”) memory is used to store instructions and data for multimedia (“MM”) client applications. As such, when a PCD is processing workloads associated with multimedia applications, there may be significant amounts of read/write traffic to and from the DDR memory component.

In a use case that includes multiple MM clients trying to simultaneously read and write from dispersed regions of the DDR, the read/write transactions may be intermingled to such an extent that the DDR is constantly being “struck” at non-contiguous addresses associated with different pages within the DDR. Consequently, because the DRR may only be capable of keeping a few memory pages actively open and ready for quick access, the intermingled strikes on the DDR may dictate constant closing of pages and opening of others. This constant opening and closing of pages as the memory controller “ping pongs” all over the DDR writing data to some addresses and reading data to others may significantly impact MM application latency, the availability of memory bandwidth, and other quality of service (“QoS”) metrics.

Accordingly, what is needed in the art is a system and method for deep coalescing memory management in a portable computing device. More specifically, what is needed in the art is a system and method that instantiates buffers in a low-latency cache memory, associates those buffers with particular MM clients, and sequentially orders transactions within the buffers so that page opening and closing in the DDR is optimized.

### SUMMARY OF THE DISCLOSURE

Various embodiments of methods and systems for deep coalescing memory management (“DCMM”) in a portable computing device (“PCD”) are disclosed. Because multiple active multimedia (“MM”) clients running on the PCD may generate a random stream of mixed read and write requests associated with data stored at non-contiguous addresses in a double data rate (“DDR”) memory component, DCMM solutions triage the requests into dedicated deep coalescing (“DC”) cache buffers to optimize read and write transactions from and to the DDR memory component.

One exemplary DCMM method includes instantiating in a cache memory, in association with a particular active MM client, a first DC buffer that is expressly for data transaction requests that are read requests and a second DC buffer that is expressly for data transaction requests that are write requests. When a write request is received from the MM client, the request is sequentially queued in the second DC buffer relative to other write requests already queued in the second DC buffer. The queued write requests are sequentially ordered in the DC buffer based on associated addresses in the DDR memory component. When a read request is received from the MM client, the requested data is returned from the first DC buffer. The data in the first DC buffer may have been previously retrieved from the DDR.

The exemplary DCMM method may monitor the capacities of the first and second DC buffers, seeking to refresh the amount of data held in the first DC buffer (the “read” buffer) and minimize the amount of data queued in the second DC buffer (the “write” buffer). When the first DC buffer becomes sufficiently depleted, the exemplary DCMM method may retrieve a block of data from the DDR, such as a memory page of data. In this way, the MM client may benefit from having its read requests serviced from the relatively fast cache memory. Similarly, when the second DC buffer becomes sufficiently full, the exemplary DCMM method may flush a block of data to the DDR, such as a memory page of contiguous data. In this way, updating data in the DDR from write requests generated by the MM client may be efficiently done as the various requests were aggregated in the second DC buffer and sequentially ordered, thus mitigating the need for the DDR to engage in page opening and closing activities to save the flushed data.

### BRIEF DESCRIPTION OF THE DRAWINGS

In the drawings, like reference numerals refer to like parts throughout the various views unless otherwise indicated. For reference numerals with letter character designations such as “102A” or “102B”, the letter character designations may differentiate two like parts or elements present in the same figure. Letter character designations for reference numerals may be omitted when it is intended that a reference numeral to encompass all parts having the same reference numeral in all figures.

FIG. 1 is a functional block diagram illustrating an exemplary, non-limiting aspect of a portable computing device (“PCD”) in the form of a wireless telephone for implementing deep coalescing memory management methods and systems;

FIG. 2 is a functional block diagram illustrating an embodiment of an on-chip system for executing deep coalescing memory management in a double data rate (“DDR”) memory using cache buffers that are each uniquely associated with read or write transaction requests from a particular active multimedia (“MM”) client;

FIG. 3 is a functional block diagram illustrating data flow through the exemplary FIG. 2 embodiment of an on-chip system for executing deep coalescing memory management in a DDR memory using cache buffers that are each uniquely associated with read or write transaction requests from a particular active multimedia (“MM”) client;

FIG. 4 is a functional block diagram illustrating an exemplary temporal flow of data through cache buffers associated with write transaction requests to a DDR memory from multiple MM clients;

FIG. 5 is a functional block diagram illustrating an exemplary temporal flow of data through cache buffers associated with read transaction requests from a DDR memory to multiple MM clients;

FIG. 6 is a schematic diagram illustrating an exemplary software architecture of the PCD of FIG. 1 for deep coalescing memory management (“DCMM”); and

FIG. 7 is a logical flowchart illustrating a method for executing deep coalescing memory management in a DDR memory using cache buffers that are each uniquely associated with read or write transaction requests from a particular active MM client.

### DETAILED DESCRIPTION

The word “exemplary” is used herein to mean serving as an example, instance, or illustration. Any aspect described herein as “exemplary” is not necessarily to be construed as exclusive, preferred or advantageous over other aspects.

In this description, the term “application” may also include files having executable content, such as: object code, scripts, byte code, markup language files, and patches. In addition, an “application” referred to herein, may also include files that are not executable in nature, such as documents that may need to be opened or other data files that need to be accessed.

In this description, reference to “DDR” memory components will be understood to envision any of a broader class of volatile random access memory (“RAM”) and will not limit the scope of the solutions disclosed herein to a specific type or generation of RAM. That is, it will be understood that various embodiments of the systems and methods provide a solution for deep coalescing memory management of read and write transaction requests to a memory component defined by pages/rows of memory banks and are not necessarily limited in application to double data rate memory. Moreover, it is envisioned that certain embodiments of the solutions disclosed herein may be applicable to DDR, DDR-2, DDR-3, low power DDR (“LPDDR”) or any subsequent generation of RAM. As would be understood by one of ordinary skill in the art, DDR RAM is organized in rows or memory pages and, as such, the terms “row” and “memory page” are used interchangeably in the present description. The memory pages of DDR may be divided into four sections, called banks in the present description. Each bank may have a register associated with it and, as such, one of ordinary skill in the art will recognize that in order to address a row of DDR (i.e., a memory page), an address of both a memory bank and a row may be required. A memory bank may be active, in which case there may be one or more open pages associated with the register of the memory bank.

In this description, the term “contiguous” is used to refer to data blocks stored in a common memory page of a DDR memory and, as such, is not meant to limit the application of solutions to reading and/or writing data blocks that are stored in an uninterrupted series of addresses on a memory page. For example, although an embodiment of the solution may read or write data blocks from/to addresses in a memory page numbered sequentially 2, 3 and 4, an embodiment may also read or write data blocks from/to addresses in a memory page numbered 2, 5, 12 without departing from the scope of the solution.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In this description, the terms “central processing unit (“CPU”),” “digital signal processor (“DSP”),” “graphical processing unit (“GPU”),” and “chip” are used interchangeably. Moreover, a CPU, DSP, GPU or a chip may be comprised of one or more distinct processing components generally referred to herein as “core(s).”

In this description, the term “portable computing device” (“PCD”) is used to describe any device operating on a limited capacity power supply, such as a battery. Although battery operated PCDs have been in use for decades, technological advances in rechargeable batteries coupled with the advent of third generation (“3G”) and fourth generation (“4G”) wireless technology have enabled numerous PCDs with multiple capabilities. Therefore, a PCD may be a cellular telephone, a satellite telephone, a pager, a PDA, a smartphone, a navigation device, a smartbook or reader, a media player, a combination of the aforementioned devices, a laptop computer with a wireless connection, among others.

In current systems and methods, multiple multimedia (“MM”) clients running simultaneously in a PCD create an intermingled flow of read and write transaction requests that necessitate access to dispersed regions of a DDR memory component. When all the transaction requests are intermingled with each other, the DDR is constantly being struck at different addresses. When an address strikes the DDR, the DDR recognizes that the address is located in a certain part of its memory and remembers that location for a period of time under the assumption that a subsequent strike in the same region may be imminent. By remembering the location of a recent strike, a DDR seeks to minimize the volume of page opening and closing required to accommodate the flow of transaction requests. Unfortunately, a DDR is limited in its ability to keep up with the pages it has open, especially under pressure of accommodating a high capacity flow of read and write transaction requests coming from multiple active MM clients.

Embodiments of systems and methods for deep coalescing memory management (“DCMM”) take advantage of the predictable read/write patterns of certain MM clients to optimize traffic to and from the DDR. To do this, DCMM embodiments may instantiate buffers in a cache memory and associate each buffer with either read requests or write requests from a particular active MM client. As transaction requests are generated by the MM clients, each is deposited into the appropriate cache buffer associated with the MM client from which it originated. Advantageously, the transaction requests may be ordered sequentially in the respective cache buffers so that when the buffers are flushed (whether “write flushed” to the DDR or “read flushed” to a MM client) the time required for accessing the DDR and completing the requests is optimized. Moreover, DCMM embodiments may sequentially flush cache buffers based on the DDR addresses of transaction requests in the buffers so that the time required for accessing the DDR and completing the requests is optimized by avoiding unnecessary random striking of the DDR. Meanwhile, the MM clients benefit from the efficient and speedy interaction with the cache (as opposed to reading and writing directly to the DDR), thereby optimizing QoS enjoyed by the PCD user.

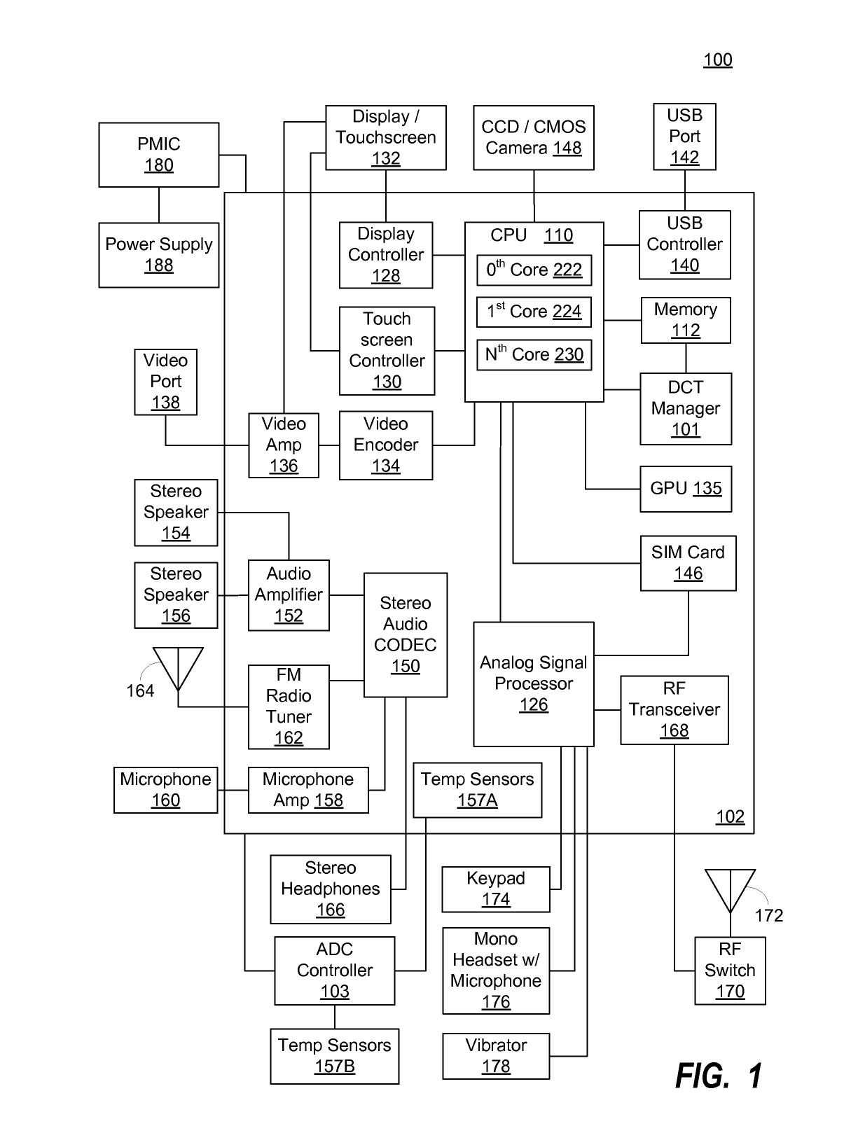

FIG. 1 is a functional block diagram illustrating an exemplary, non-limiting aspect of a PCD 100 in the form of a wireless telephone for implementing deep coalescing memory management (“DCMM”) methods and systems. As shown, the PCD 100 includes an on-chip system 102 that includes a multi-core central processing unit (“CPU”) 110 and an analog signal processor 126 that are coupled together. The CPU 110 may comprise a zeroth core 222, a first core 224, and an Nth core 230 as understood by one of ordinary skill in the art. Further, instead of a CPU 110, a digital signal processor (“DSP”) may also be employed as understood by one of ordinary skill in the art.

In general, the deep coalescing traffic (“DCT”) manager 101 may be formed from hardware and/or firmware and may be responsible for managing read and/or write requests for instructions and/or data stored in a DDR memory component 115 (depicted in FIG. 1 as memory 112). Advantageously, using cache memory buffers instantiated in association with particular active multimedia clients, a DCD manager 101 may receive the transaction requests, sequentially order them in an appropriate cache buffer and then transfer data in and out of the cache buffers in relatively large bursts. It is envisioned that write bursts to the DDR, for instance, may be sequentially ordered bytes of data in chunks that are a memory page in length. By sequentially ordering the data requests according to their memory addresses, and then timing read or write transactions such that a full or near full memory page is updated in the DDR, access efficiency to the DDR may be optimized.

As illustrated in FIG. 1, a display controller 128 and a touch screen controller 130 are coupled to the digital signal processor 110. A touch screen display 132 external to the on-chip system 102 is coupled to the display controller 128 and the touch screen controller 130. PCD 100 may further include a video encoder 134, e.g., a phase-alternating line (“PAL”) encoder, a sequential couleur avec memoire (“SECAM”) encoder, a national television system(s) committee (“NTSC”) encoder or any other type of video encoder 134. The video encoder 134 is coupled to the multi-core CPU 110. A video amplifier 136 is coupled to the video encoder 134 and the touch screen display 132. A video port 138 is coupled to the video amplifier 136. As depicted in FIG. 1, a universal serial bus (“USB”) controller 140 is coupled to the CPU 110. Also, a USB port 142 is coupled to the USB controller 140. A memory 112, which may include a PoP memory, a cache 116, a mask ROM/Boot ROM, a boot OTP memory, a DDR memory 115 (see subsequent Figures) may also be coupled to the CPU 110. A subscriber identity module (“SIM”) card 146 may also be coupled to the CPU 110. Further, as shown in FIG. 1, a digital camera 148 may be coupled to the CPU 110. In an exemplary aspect, the digital camera 148 is a charge-coupled device (“CCD”) camera or a complementary metal-oxide semiconductor (“CMOS”) camera.

As further illustrated in FIG. 1, a stereo audio CODEC 150 may be coupled to the analog signal processor 126. Moreover, an audio amplifier 152 may be coupled to the stereo audio CODEC 150. In an exemplary aspect, a first stereo speaker 154 and a second stereo speaker 156 are coupled to the audio amplifier 152. FIG. 1 shows that a microphone amplifier 158 may be also coupled to the stereo audio CODEC 150. Additionally, a microphone 160 may be coupled to the microphone amplifier 158. In a particular aspect, a frequency modulation (“FM”) radio tuner 162 may be coupled to the stereo audio CODEC 150. Also, an FM antenna 164 is coupled to the FM radio tuner 162. Further, stereo headphones 166 may be coupled to the stereo audio CODEC 150.

FIG. 1 further indicates that a radio frequency (“RF”) transceiver 168 may be coupled to the analog signal processor 126. An RF switch 170 may be coupled to the RF transceiver 168 and an RF antenna 172. As shown in FIG. 1, a keypad 174 may be coupled to the analog signal processor 126. Also, a mono headset with a microphone 176 may be coupled to the analog signal processor 126. Further, a vibrator device 178 may be coupled to the analog signal processor 126. FIG. 1 also shows that a power supply 188, for example a battery, is coupled to the on-chip system 102 through a power management integrated circuit (“PMIC”) 180. In a particular aspect, the power supply 188 includes a rechargeable DC battery or a DC power supply that is derived from an alternating current (“AC”) to DC transformer that is connected to an AC power source.

The CPU 110 may also be coupled to one or more internal, on-chip thermal sensors 157A as well as one or more external, off-chip thermal sensors 157B. The on-chip thermal sensors 157A may comprise one or more proportional to absolute temperature (“PTAT”) temperature sensors that are based on vertical PNP structure and are usually dedicated to complementary metal oxide semiconductor (“CMOS”) very large-scale integration (“VLSI”) circuits. The off-chip thermal sensors 157B may comprise one or more thermistors. The thermal sensors 157 may produce a voltage drop that is converted to digital signals with an analog-to-digital converter (“ADC”) controller (not shown). However, other types of thermal sensors 157 may be employed.

The touch screen display 132, the video port 138, the USB port 142, the camera 148, the first stereo speaker 154, the second stereo speaker 156, the microphone 160, the FM antenna 164, the stereo headphones 166, the RF switch 170, the RF antenna 172, the keypad 174, the mono headset 176, the vibrator 178, thermal sensors 157B, the PMIC 180 and the power supply 188 are external to the on-chip system 102. It will be understood, however, that one or more of these devices depicted as external to the on-chip system 102 in the exemplary embodiment of a PCD 100 in FIG. 1 may reside on chip 102 in other exemplary embodiments.

In a particular aspect, one or more of the method steps described herein may be implemented by executable instructions and parameters stored in the memory 112 or as form the DCT manager 101. Further, the DCT manager 101, the memory 112, the instructions stored therein, or a combination thereof may serve as a means for performing one or more of the method steps described herein.

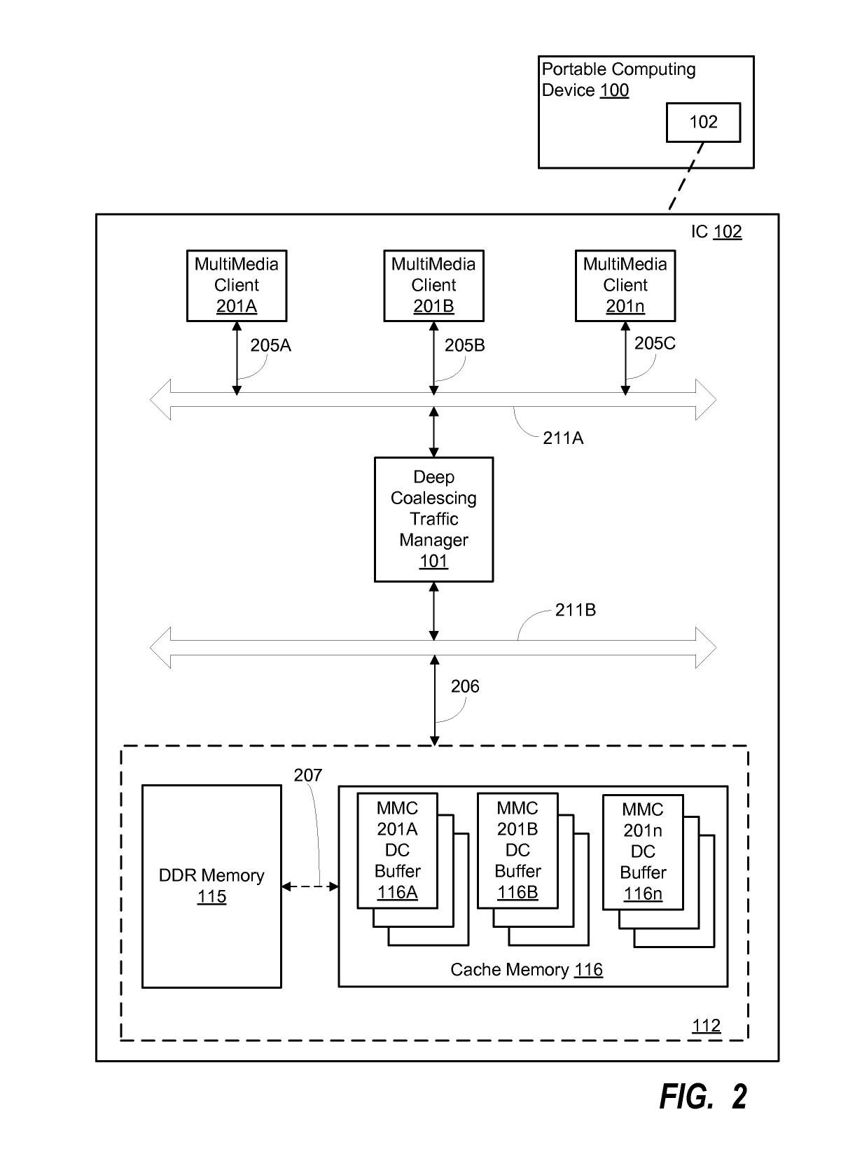

FIG. 2 is a functional block diagram illustrating an embodiment of an on-chip system 102 for executing deep coalescing memory management in a double data rate (“DDR”) memory 115 using cache buffers 116 that are each uniquely associated with read or write transaction requests from a particular active multimedia (“MM”) client 201. As indicated by the arrows 205 in the FIG. 2 illustration, an active MM client 201 may be submitting transaction requests for either reading data from the DDR 115 or writing data to the DDR 115, or a combination thereof, via a system bus 211. As is understood by one of ordinary skill in the art, the CPU 110 in executing a workload associated with a given MM client 201 could be fetching and/or updating instructions and/or data that are stored at the address(es) of the DDR memory 115.

To avoid the random flow of read and write transaction requests 205 striking the DDR 115, the DCT manager 101 may filter the requests into DC buffers 116 uniquely associated with the active MM clients 201. Write requests emanating from MM client 201A, for example, may be queued in MMC 201A DC Buffer 116A while read requests from MM client 201A are queued in a different DC buffer 116. Read and write requests from other MM clients 201 may be queued in other DC buffers 116 that were instantiated in association with, and for the benefit of, those other MM clients 201.

Recognizing the data access patterns associated with certain MM clients 201, the DCT manager 101 may sequentially order the write requests in the appropriate DC buffers 116 until a full page, or other optimal data block size, of requests has accumulated in a given DC “write” buffer, at which time the DCT manager 101 may trigger a flush 207 of the given “write” buffer to the DDR 115. Similarly, the DCT manager 101 may monitor the capacity of a given “read” buffer and, recognizing that data levels in the DC “read” buffer are low, trigger a read transaction from the DDR 115 in a full page block, or other optimal block size, into the “read” buffer. In these ways, DCMM embodiments seek to optimize transactions to and from the DDR 115 as blocks of data transactions associated with addresses in a common memory page are conducted sequentially.

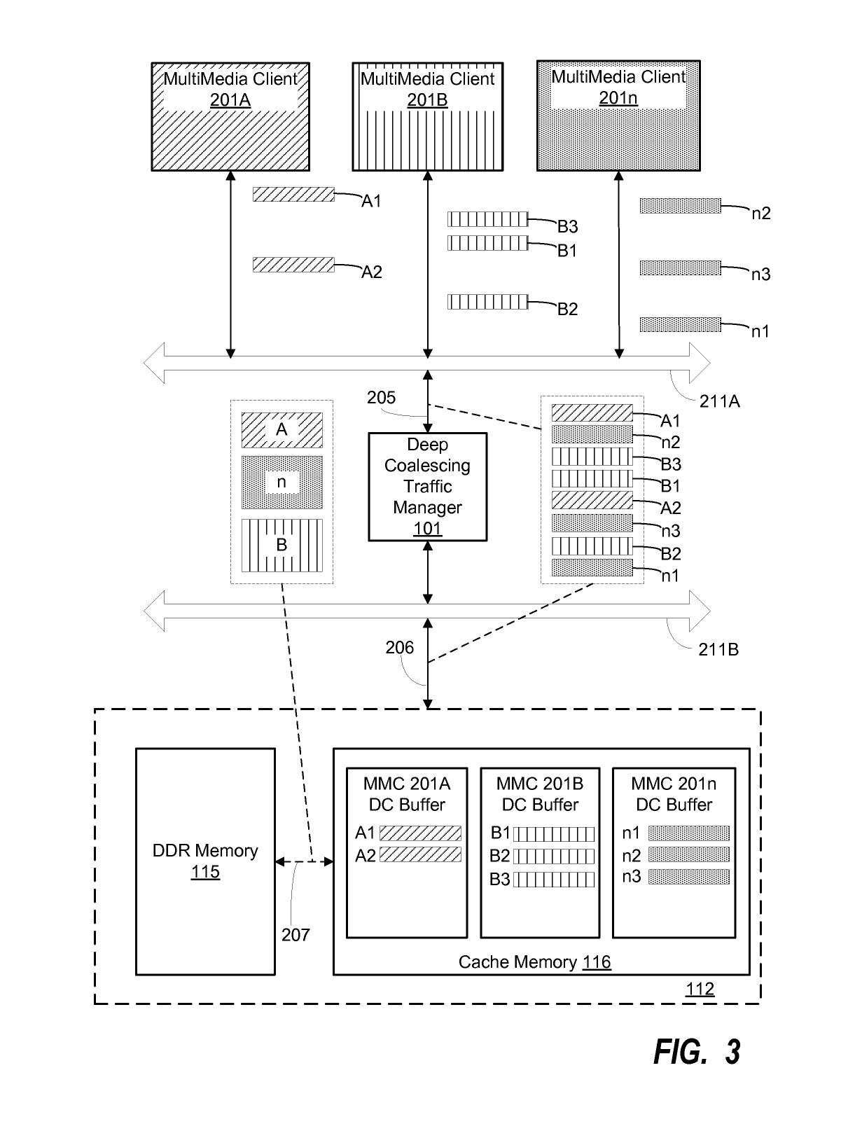

FIG. 3 is a functional block diagram illustrating data flow through the exemplary FIG. 2 embodiment of an on-chip system 102 for executing deep coalescing memory management in a DDR memory 115 using cache buffers 116 that are each uniquely associated with read or write transaction requests from a respective active multimedia (“MM”) client 201. In the FIG. 3 illustration, it can be seen that individual transactions seeking to read data from, or write data to, the DDR 115 are originating from the respective MM clients 201. Notably, in describing the FIG. 3 illustration, the data transaction requests emanating from the MM clients 201 may be assumed to be “write” requests flowing down to the DDR 115, although it will be understood from the description of FIG. 3 and subsequent figures that the data transaction requests depicted in the FIG. 3 illustration may be “read” requests flowing up from the DDR 115.

For example, referring to MM client 201A, it can be seen that two exemplary data transactions, A2 and A1, have originated from MM client 201A. Similarly, data transactions B2, B1 and B3 are shown to have originated from MM client 201B while data transactions n1, n3 and n2 have originated from MM client 201n. Notably, although the illustrations depict three active MM clients 201, one of ordinary skill in the art will recognize that DCMM embodiments may be applicable for data transaction management in systems having any number of active MM clients.

Returning to the FIG. 3 illustration, the individual data transactions may be in the form of read requests or write requests, as determined by the given MM client 201 from which a given data transaction request emanated. It is envisioned that a data transaction request may be associated with any amount of data associated with a given memory address in the DDR 115.

Because the data transaction requests from one MM client 201 may originate independently from data transaction requests originated from a different MM client 201, the requests may arrive on bus 211A randomly, as depicted in the FIG. 3 illustration on communication links 205 and 206 (ordered according to arrival: n1, B2, n3, A2, B1, B3, n2, A1). The DCT manager 101 may marshal over bus 211B the data transaction requests into deep coalescing buffers 116A, 116B, 116n uniquely associated with MM clients 201A, 201B and 201n, respectively. As can further be seen in the FIG. 3 illustration, the DCT manager 101 may sequentially order the data transaction requests in the DC buffers 116 according to addresses in the DDR 115 for the data. For example, referring to DC buffer 116B, which is associated with MM client 201B, the data transaction requests are ordered in DC buffer 116B sequentially (B1, B2, B3) even though the requests originated from MM client 201B out of order relative to their DDR address locations (B2, B1, B3).

Moreover, a given MM client 201 may be executing a single computing thread, for example, such that the associated DC buffer 116 is filled sequentially without the DCT manager 101 having to reorder the transaction requests. In other applications, however, a DC buffer 116 may be filled in reverse, from finish to start of a computing thread, or from a center point in the thread to an end point, such as may be the case when building or modifying list structures. Further, it is envisioned that an MM client 201, although singularly “functional,” may include multi-threaded parallel hardware that are executing multiple threads in parallel which send transaction requests to the associated DC buffer 116. In such case, the associated DC buffer 116 may be large with different threads assigned to different spatial regions or, as another example, the associated DC buffer 116 may require multiple iterations of work to be performed on the cached data before being flushed to the DDR 115.

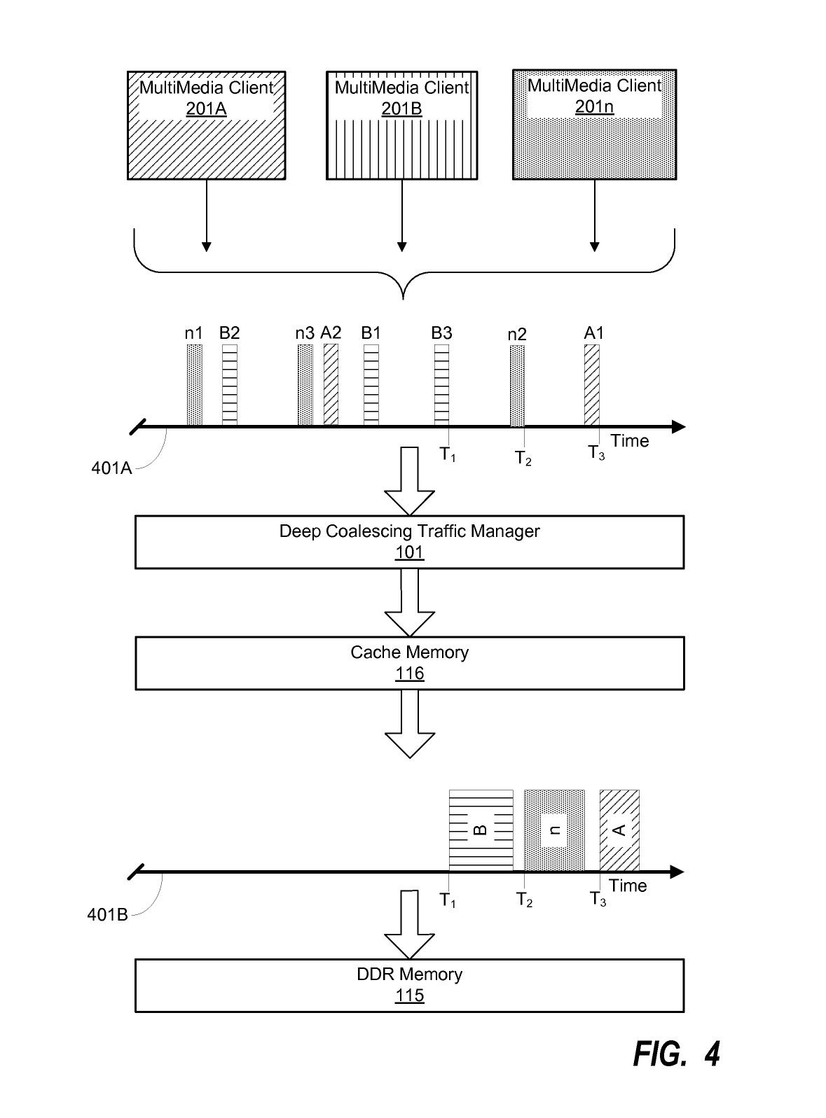

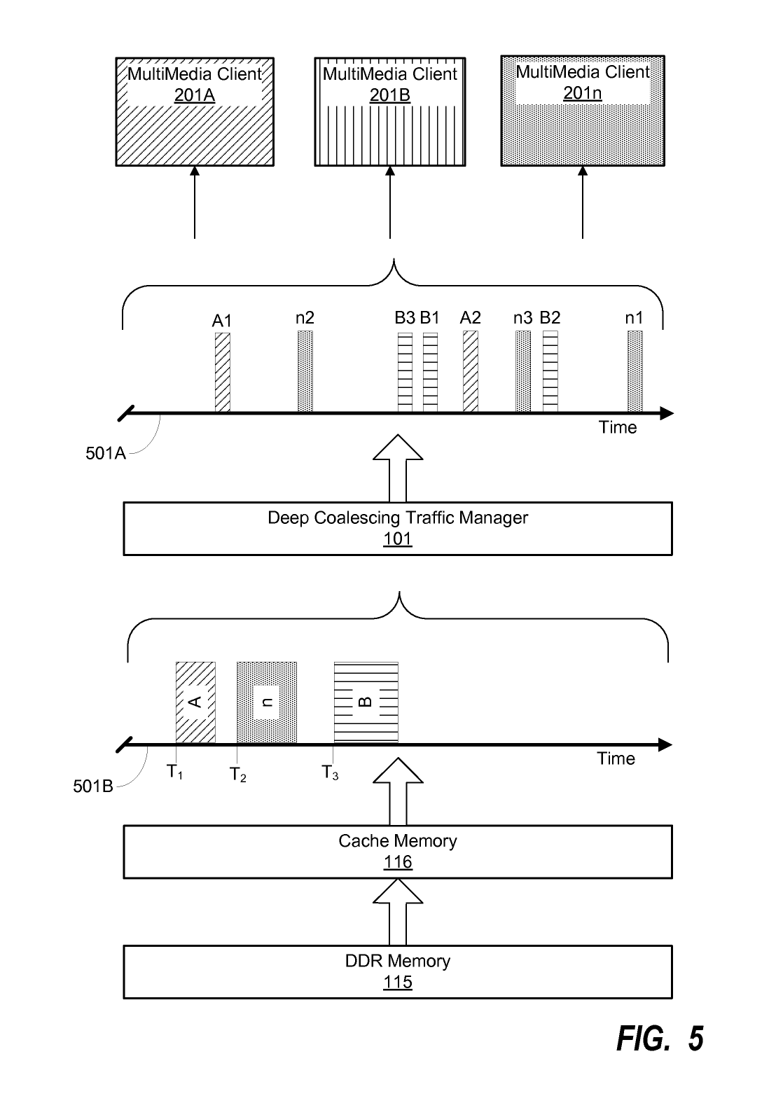

Returning to the FIG. 3 illustration, the DCT manager 101 may monitor the capacities of the various DC buffers 116, seeking to keep DC buffers associated with “read” data full and DC buffers associated with “write” data empty. Because the transaction requests are sequentially ordered in the respective buffers, a “write” buffer may be flushed to the DDR 115 a memory page (or some other optimal data block size) at a time, thereby enabling the DDR 115 to update sequential addresses in a given memory page (see also FIG. 4 illustration). Similarly, and as more specifically described relative to FIG. 5, data may be written to the DC buffers from the DDR 115 a memory page (or some other optimal block size) at a time. Page sized transactions of sequentially ordered data to and from the DDR 115 is depicted in FIG. 3 in association with transmission 207. Moreover, it is envisioned that certain DCMM embodiments may flush DC buffers 116 to DDR 115 in a sequential order according to DDR addresses associated with transaction requests in the DC buffers 116. In this way, DCMM embodiments may reorder a queue of buffers ready for flushing such that the time required to lock out the DDR 115 and update the data stored therein is optimized by minimizing the need to “ping pong” around the DDR 115 opening and closing pages.

Notably, regarding the size of deep coalescing cache buffers in a given DCMM system 102, it is envisioned that the size may be determined based on the known pattern of data updates and retrieval for a given MM client. As such, it is envisioned that DC buffer size may be determined based on a likelihood that the size lends itself to being consistently filled with sequential data transactions (if a “read” buffer) or consistently emptied with a block of sequential data transactions (if a “write” buffer).

FIG. 4 is a functional block diagram illustrating an exemplary temporal flow of data through a cache buffer 116 that is associated with “write” transaction requests to a DDR memory 115 from MM clients 201. Notably, in the FIG. 4 illustration, the ordered arrival of the exemplary data transaction requests is consistent with the order of arrival depicted in the FIG. 3 illustration and, as such, for the purpose of understanding the FIG. 4 illustration within the context of the FIG. 3 illustration, the data transaction requests from MM clients 201 in FIG. 3 may be assumed to all be “write” transactions. Even so, it is envisioned that data transaction requests emanating from multiple MM clients 201 in a given DCMM system 102 may be a mix of “read” and “write” requests, as would be understood by one of ordinary skill in the art.

In the FIG. 4 illustration, data transaction “write” requests are depicted as originating from MM clients 201. Requests A1-A2 originate from MM client 201A, requests B1-B3 originate from MM client 201B and requests n1-n3 originate from MM client 201n. As can be seen on timeline 401A, the order of arrival of the data transaction write requests is n1, B2, n3, A2, B1, B3, n2 and A1.

The requests are managed by the deep coalescing traffic manager 101. As the requests arrive, the DCT manager 101 triages the requests into DC cache buffers instantiated in cache memory 116 for coalescing of write requests uniquely associated with each of the MM clients 201. As previously described, the DCT manager 101 may order the requests in the respective DC write buffers such that the requests are sequentially ordered according to DDR addresses associated with the data in the write requests.

The DCT manager 101 may have determined a given DC cache buffer size based on a recognized pattern of write request generation from a given MM client 201. For example, assuming that the data transaction requests depicted in the FIG. 4 illustration are each eight bytes in size, the DCT manager 101 may have determined the size of a DC cache “write” buffer for MM client 201A to be sixteen bytes in size because the pattern of write request generation coming out of MM client 201A lends itself to the generation of two write transaction requests (A2, A1) before moving on to a different workload. Similarly, the DCT manager 101 may have determined the size of a DC cache “write” buffer for MM client 201B to be twenty-four bytes in size because the pattern of write request generation coming out of MM client 201B lends itself to the generation of three write transaction requests (B2, B1, B3) before moving on to a different workload.

Returning to the FIG. 4 illustration, the DCT manager 101 may recognize when a given DC write buffer in the cache memory 116 is full or, perhaps, has been filled to a certain threshold capacity. For example, at time T₁ the DCT manager 101 may recognize that a DC write buffer associated with MM client 201B has been filled with twenty-four bytes of data earmarked for updating in, i.e. “writing” to, the DDR 115. Accordingly, the DCT manager 101 may trigger the flush of the write transaction data (B1, B2, B3) to the DDR 115. Advantageously, because the write transaction data from MM client 201B had been sequentially ordered in the dedicated cache buffer, a single page in the DDR 115 associated with addresses for data B1, B2 and B3 may be opened and quickly updated, thereby minimizing the duration for locking access to the DDR while the MM client 201B write requests are satisfied.

As can further be seen from the FIG. 4 illustration, the DC cache buffers associated with write requests from MM clients 201 may be filled at times T₁ (MM client 201B), T₂ (MM client 201n) and T₃ (MM client 201A), respectively. Consequently, the DCT manager 101 may recognize that the respective DC cache buffers are full and ready for flushing to the DDR 115 beginning on timeline 401B substantially at times T₁ for the write transaction requests associated with MM client 201B, T₂ for the write transaction requests associated with MM client 201n, and T₃ for the write transaction requests associated with MM client 201A.

FIG. 5 is a functional block diagram illustrating an exemplary temporal flow of data through a cache buffer 116 that is associated with “read” transaction requests from a DDR memory 115 to MM clients 201. Notably, in the FIG. 5 illustration, the ordered delivery to the MM clients 201 of the data associated with the exemplary data transaction requests is consistent with the order of delivery depicted in the FIG. 3 illustration and, as such, for the purpose of understanding the FIG. 5 illustration within the context of the FIG. 3 illustration, the data transaction requests to MM clients 201 in FIG. 3 may be assumed to all be “read” transactions. Even so, it is envisioned that data transaction requests originating from multiple MM clients 201 in a given DCMM system 102 may be a mix of “read” and “write” requests, as would be understood by one of ordinary skill in the art.

In the FIG. 5 illustration, data transaction “read” requests are depicted as originating from MM clients 201. Requests A1-A2 originate from MM client 201A, requests B1-B3 originate from MM client 201B and requests n1-n3 originate from MM client 201n. As can be seen on timeline 501A, the deep coalescing traffic manager 101 coordinates to satisfy the data transaction read requests from the cache memory 116 in the following order: A1, n2, B3, B1, A2, n3, B2 and n1.

The requests are managed by the deep coalescing traffic manager 101. As DC cache buffers associated with read requests for each of the MM clients 201 become depleted, the DCT manager 101 triggers the DDR memory 115 to copy contiguous blocks of data into the DC cache “read” buffers. As previously described, the DCT manager 101 may order the requests in the respective DC read buffers such that the requests are sequentially ordered according to DDR addresses associated with the data in the read requests.

The DCT manager 101 may have determined a given DC cache read buffer size based on a recognized pattern of read request generation from a given MM client 201. For example, assuming that the data transaction requests depicted in the FIG. 5 illustration are each eight bytes in size, the DCT manager 101 may have determined the size of a DC cache “read” buffer for MM client 201A to be sixteen bytes in size because the pattern of read request generation coming out of MM client 201A lends itself to the generation of two read transaction requests (A1, A2) before moving on to a different workload. Similarly, the DCT manager 101 may have determined the size of a DC cache “read” buffer for MM client 201B to be twenty-four bytes in size because the pattern of read request generation coming out of MM client 201B lends itself to the generation of three read transaction requests (B3, B1, B2) before moving on to a different workload.

Returning to the FIG. 5 illustration, the DCT manager 101 may recognize when a given DC read buffer in the cache memory 116 is empty or, perhaps, has been emptied to a certain threshold capacity. For example, at time T₁ the DCT manager 101 may recognize that a DC read buffer associated with MM client 201A has been depleted to a point that sixteen bytes of data may be efficiently copied into the cache buffer from the DDR 115. Accordingly, the DCT manager 101 may trigger a “read flush” of a block of data (A1, A2) from the DDR 115 to the DC cache read buffer associated with MM client 201A. Advantageously, a single page in the DDR 115 associated with addresses for data A1, A2 may be opened and quickly copied to the appropriate DC cache buffer, thereby minimizing the duration for locking access to the DDR while the data that will be needed by MM client 201A is copied to its dedicated cache buffer.

As can further be seen from the FIG. 5 illustration, the DC cache buffers associated with read requests from MM clients 201 may be filled beginning at times T₁ (MM client 201A), T₂ (MM client 201n) and T₃ (MM client 201B), respectively. Consequently, the DCT manager 101 may recognize that the respective DC cache buffers are full and available for satisfying read transaction requests from the MM clients 201. Looking to timeline 501B, data copied in optimally sized blocks from the DDR 115 to the DC buffers in the cache memory 116 may be available to satisfy read requests of the MM clients 201 once the data blocks have been successfully copied to the cache 116. Advantageously, because the cache 116 may be more responsive to data requests from the MM clients 201 than the DDR 115, embodiments of DCMM systems and methods may optimize QoS experienced by a PCD 100 user.

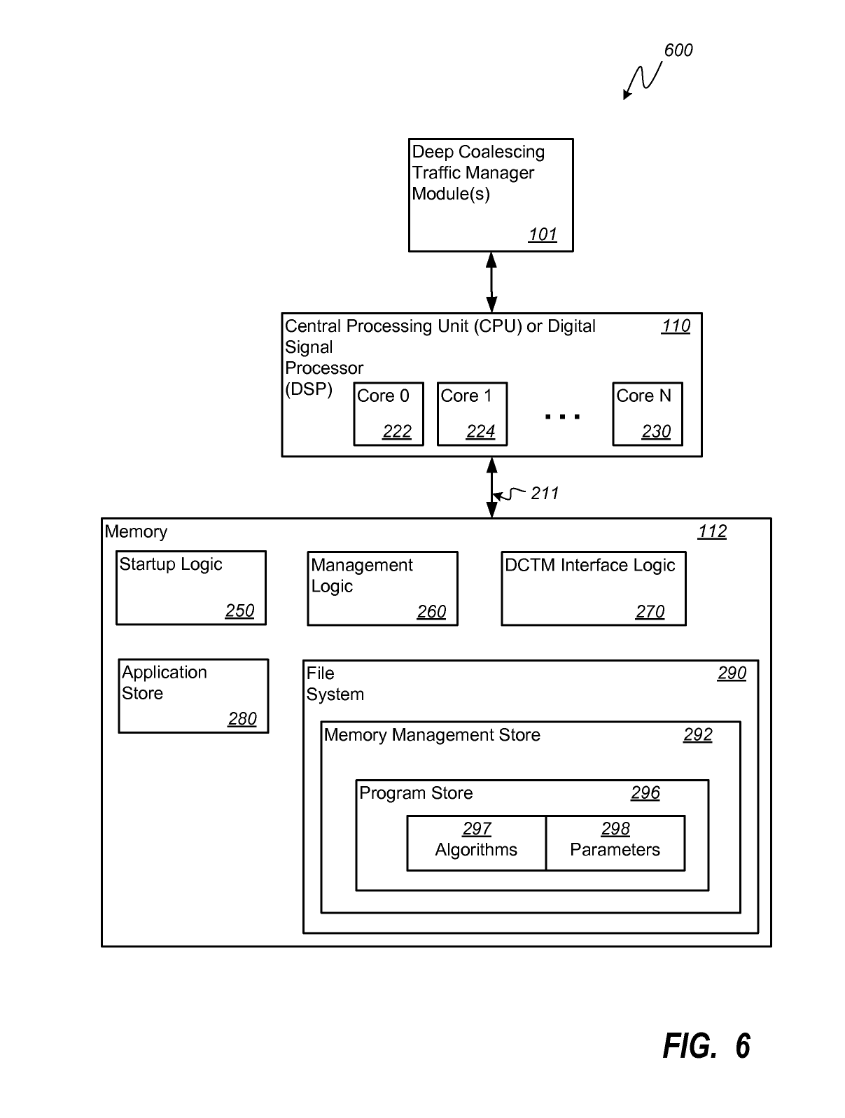

FIG. 6 is a schematic diagram illustrating an exemplary software architecture 600 of the PCD 100 of FIG. 1 for deep coalescing memory management (“DCMM”). Any number of algorithms may form or be part of at least one memory management policy that may be applied by the DCT manager module 101. Recognizing patterns of data transaction requests generated by workload processing associated with certain active multimedia clients, the DCT manager module 101 instantiates optimally sized cache buffers and uniquely associates those cache buffers with the certain active multimedia clients. By doing so, the DCT manager module 101 optimizes QoS delivered to a user of the PCD because 1) the multimedia clients benefit from the quick access to data stored in the dedicated cache buffers and 2) the sequentially ordered write requests in the cache buffers lend to efficient page opening and closing in the DDR 115 when data is being updated.

As illustrated in FIG. 6, the CPU or digital signal processor 110 is coupled to the memory 112 via a bus 211. The CPU 110, as noted above, is a multiple-core processor having N core processors. That is, the CPU 110 includes a first core 222, a second core 224, and an N^{th} core 230. As is known to one of ordinary skill in the art, each of the first core 222, the second core 224 and the N^{th} core 230 are available for supporting a dedicated application or program. Alternatively, one or more applications or programs may be distributed for processing across two or more of the available cores.

The CPU 110 may receive commands from the DCT manager module(s) 101 that may comprise software and/or hardware. If embodied as software, the module(s) 101 comprise instructions that are executed by the CPU 110 that issues commands to other application programs being executed by the CPU 110 and other processors.

The first core 222, the second core 224 through to the Nth core 230 of the CPU 110 may be integrated on a single integrated circuit die, or they may be integrated or coupled on separate dies in a multiple-circuit package. Designers may couple the first core 222, the second core 224 through to the N^{th} core 230 via one or more shared caches and they may implement message or instruction passing via network topologies such as bus, ring, mesh and crossbar topologies.

Bus 211 may include multiple communication paths via one or more wired or wireless connections, as is known in the art. The bus 211 may have additional elements, which are omitted for simplicity, such as controllers, buffers (caches), drivers, repeaters, and receivers, to enable communications. Further, the bus 211 may include address, control, and/or data connections to enable appropriate communications among the aforementioned components.

When the logic used by the PCD 100 is implemented in software, as is shown in FIG. 6, it should be noted that one or more of startup logic 250, management logic 260, DCTM interface logic 270, applications in application store 280 and portions of the file system 290 may be stored on any computer-readable medium for use by, or in connection with, any computer-related system or method.

In the context of this document, a computer-readable medium is an electronic, magnetic, optical, or other physical device or means that can contain or store a computer program and data for use by or in connection with a computer-related system or method. The various logic elements and data stores may be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device.

The computer-readable medium can be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection (electronic) having one or more wires, a portable computer diskette (magnetic), a random-access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, for instance via optical scanning of the paper or other medium, then compiled, interpreted or otherwise processed in a suitable manner if necessary, and then stored in a computer memory.

In an alternative embodiment, where one or more of the startup logic 250, management logic 260 and perhaps the DCTM interface logic 270 are implemented in hardware, the various logic may be implemented with any or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The memory 112 is a non-volatile data storage device such as a flash memory or a solid-state memory device. Although depicted as a single device, the memory 112 may be a distributed memory device with separate data stores coupled to the digital signal processor 110 (or additional processor cores).

The startup logic 250 includes one or more executable instructions for selectively identifying, loading, and executing a select program for managing or controlling the performance of one or more of the available cores such as the first core 222, the second core 224 through to the N^{th} core 230. The startup logic 250 may identify, load and execute a select DCMM program. An exemplary select program may be found in the program store 296 of the embedded file system 290 and is defined by a specific combination of a deep coalescing algorithm 297 and a set of parameters 298 for a given MM client that may include timing parameters, data amounts, patterns of data transaction requests, etc. The exemplary select program, when executed by one or more of the core processors in the CPU 110 may operate in accordance with one or more signals provided by the DCT manager module 101 to triage write and read requests in dedicated deep coalescing cache buffers.

The management logic 260 includes one or more executable instructions for terminating a memory management program on one or more of the respective processor cores, as well as selectively identifying, loading, and executing a more suitable replacement program for managing memory in response to read and write data transaction requests originating from various active multimedia clients. The management logic 260 is arranged to perform these functions at run time or while the PCD 100 is powered and in use by an operator of the device. A replacement program may be found in the program store 296 of the embedded file system 290 and, in some embodiments, may be defined by a specific combination of an algorithm 297 and a set of parameters 298.

The interface logic 270 includes one or more executable instructions for presenting, managing and interacting with external inputs to observe, configure, or otherwise update information stored in the embedded file system 290. In one embodiment, the interface logic 270 may operate in conjunction with manufacturer inputs received via the USB port 142. These inputs may include one or more programs to be deleted from or added to the program store 296. Alternatively, the inputs may include edits or changes to one or more of the programs in the program store 296. Moreover, the inputs may identify one or more changes to, or entire replacements of one or both of the startup logic 250 and the management logic 260. By way of example, the inputs may include a change to the optimum cache buffer size for a given multimedia client.

The interface logic 270 enables a manufacturer to controllably configure and adjust an end user's experience under defined operating conditions on the PCD 100. When the memory 112 is a flash memory, one or more of the startup logic 250, the management logic 260, the interface logic 270, the application programs in the application store 280 or information in the embedded file system 290 may be edited, replaced, or otherwise modified. In some embodiments, the interface logic 270 may permit an end user or operator of the PCD 100 to search, locate, modify or replace the startup logic 250, the management logic 260, applications in the application store 280 and information in the embedded file system 290. The operator may use the resulting interface to make changes that will be implemented upon the next startup of the PCD 100. Alternatively, the operator may use the resulting interface to make changes that are implemented during run time.

The embedded file system 290 includes a hierarchically arranged memory management store 292. In this regard, the file system 290 may include a reserved section of its total file system capacity for the storage of information for the configuration and management of the various parameters 298 and deep coalescing memory management algorithms 297 used by the PCD 100. As shown in FIG. 6, the memory management store 292 includes a program store 296, which includes one or more deep coalescing memory management programs that may include algorithms for instantiating deep coalescing cache buffers, sequentially ordering data transaction requests and updating/retrieving data stored in a DDR memory 115.

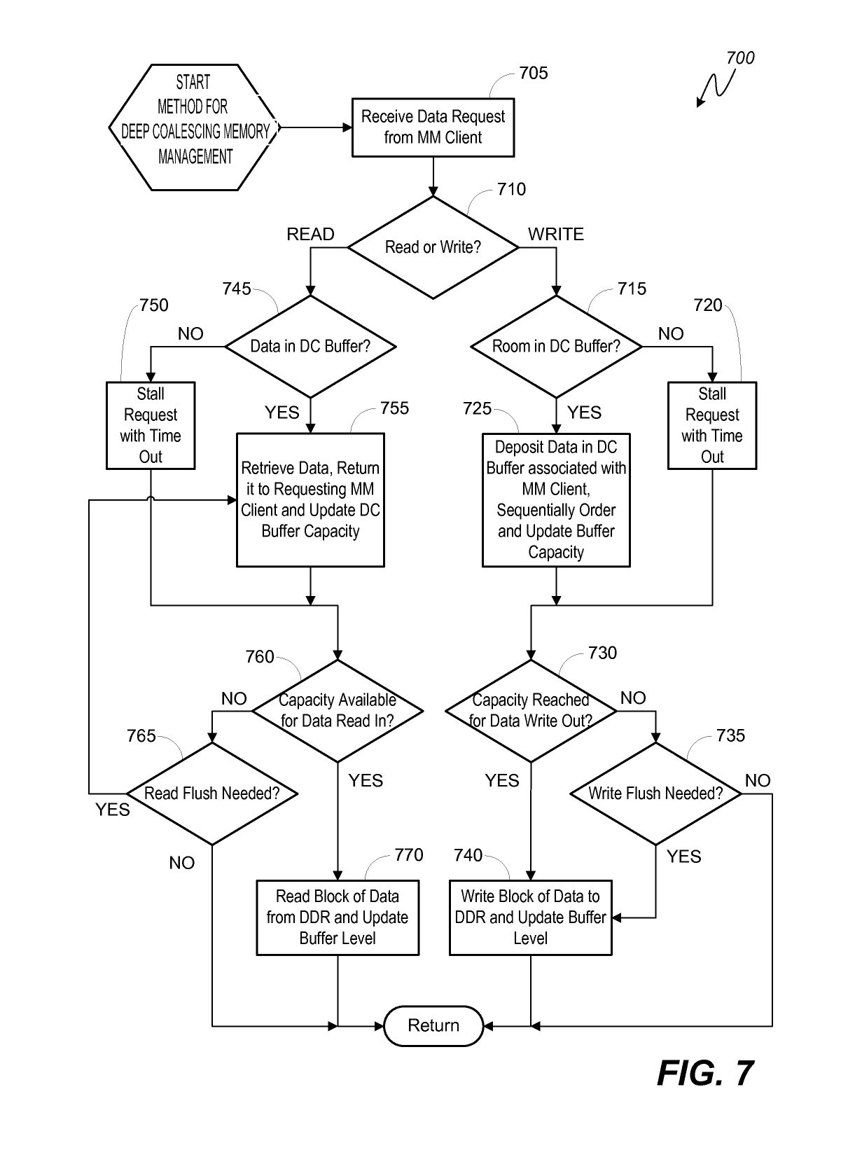

FIG. 7 is a logical flowchart illustrating a method 700 for executing deep coalescing memory management in a DDR memory 115 using cache buffers 116 that are each uniquely associated with read or write transaction requests from a particular active MM client 201. Beginning at block 705, the DCT manager module 101 may recognize a data transaction request originating from an active MM client 201. At decision block 710, the DCT manager module 101 may determine whether the data transaction request is a “read” request for data stored at an address in the DDR 115 or a “write” request for updating data stored at an address in the DDR 115.

If the data transaction request of block 705 is a “write” request, then the method proceeds to decision block 715. Because the DCT manager module 101 may be seeking to keep as empty as possible a deep coalescing buffer instantiated in the cache 116 for the express queuing of write requests originating from the active MM client 201, at decision block 715 the DCT manager module 101 may take note of the available capacity in the particular DC cache buffer that is uniquely associated with the MM client 201 from which the write request originated. If there is no room in the DC buffer, the method 700 may proceed to block 720 and stall the MM client 201 until capacity in the DC buffer becomes available for queuing the write request. If there is room in the DC buffer, the “yes” branch is followed from decision block 715 to block 725 and the write request transaction data is deposited in the dedicated DC buffer and sequentially order relative to other data already queued in the DC buffer (i.e., other write transaction requests previously generated by the MM client 201).

Proceeding from blocks 720 or 725, the method 700 moves to decision block 730. At decision block 730, the DCT manager module 101 may determine whether the DC buffer contains an optimum amount of transaction requests for writing to the DDR 115. If “yes,” then the method 700 proceeds to block 740 and a block of data, sequentially ordered according to its associated addresses in the DDR 115, is written to the DDR 115. If the DC buffer does not contain an optimum amount of data for writing to the DDR 115, the method 700 may proceed to decision block 735 to determine whether the DC buffer should be flushed to the DDR 115 regardless. If “yes,” then the method 700 moves to block 740 and the data is written to the DDR 115. The “yes” branch of decision block 735 may be triggered by any number of conditions including, but not limited to, a duration of time that the DC buffer has existed, the state of a workload being processed by the associated MM client 201, the amount of data in the DC buffer, etc. Essentially, it is envisioned that any trigger may be used to dictate whether a DC buffer is ripe for flushing and, as such, embodiments of the solutions are not limited to particular amounts of data aggregating in a DC buffer. Moreover, it is envisioned that DCMM embodiments may be opportunistic in setting thresholds for triggering of data flushes. If the “no” branch is followed from decision block 735, then the method returns.

Returning to decision block 710 in the method 700, if the data transaction request received at block 705 is a “read” request, then the method 700 proceeds to decision block 745. At decision block 745, the DCT manager module 101 may determine if the requested data is already queued in a DC buffer instantiated expressly for “read” requests associated with the particular MM client 201 from which the data transaction request originated. If “no,” then the method 700 moves to block 750 and the MM client 201 is stalled until the requested data can be retrieved from the DDR 115 and stored in the associated DC buffer as described below. It is envisioned, however, that some embodiments may not stall the MM client 201 when the requested data is not already queued in the DC buffer but, rather, opt to directly query the data from the DDR 115. If the “yes” branch is followed from decision block 745, then at block 755 the requested data is returned from the DC buffer to the MM client 201 and the capacity level of the DC buffer updated.

Moving from blocks 750 or 755, the method 700 may proceed to decision block 760. At decision block 760, the DCT manager module 101 may determine whether the DC buffer associated with read requests for the MM client 201 is in need of replenishing. If “yes,” then the method 700 proceeds to block 770 and an optimum amount of data is retrieved from the DDR 115 and stored in the dedicated DC buffer pending a read request from the associated MM client 201 for data included in the block. If the “no” branch is followed from decision block 760, then the method 700 may determine at decision block 765 whether the DC buffer associated with read requests should be “read flushed” up to the MM client or otherwise cleared out for fresh data. Essentially, it is envisioned that any trigger may be used to dictate whether a DC buffer is ripe for flushing and, as such, embodiments of the solutions are not limited to particular amounts of data aggregating in a DC buffer. Moreover, it is envisioned that DCMM embodiments may be opportunistic in setting thresholds for triggering of data flushes. If “yes,” then the method 700 may clear out the DC buffer or return to block 755. If “no,” then the method may return.

Certain steps in the processes or process flows described in this specification naturally precede others for the invention to function as described. However, the invention is not limited to the order of the steps described if such order or sequence does not alter the functionality of the invention. That is, it is recognized that some steps may performed before, after, or parallel (substantially simultaneously with) other steps without departing from the scope and spirit of the invention. In some instances, certain steps may be omitted or not performed without departing from the invention. Further, words such as “thereafter”, “then”, “next”, etc. are not intended to limit the order of the steps. These words are simply used to guide the reader through the description of the exemplary method.

Additionally, one of ordinary skill in programming is able to write computer code or identify appropriate hardware and/or circuits to implement the disclosed invention without difficulty based on the flow charts and associated description in this specification, for example. Therefore, disclosure of a particular set of program code instructions or detailed hardware devices is not considered necessary for an adequate understanding of how to make and use the invention. The inventive functionality of the claimed computer implemented processes is explained in more detail in the above description and in conjunction with the drawings, which may illustrate various process flows.

In one or more exemplary aspects, the functions described may be implemented in hardware, software, firmware, or any combination thereof. If implemented in software, the functions may be stored on or transmitted as one or more instructions or code on a computer-readable medium. Computer-readable media include both computer storage media and communication media including any medium that facilitates transfer of a computer program from one place to another. A storage media may be any available media that may be accessed by a computer. By way of example, and not limitation, such computer-readable media may comprise RAM, ROM, EEPROM, CD-ROM or other optical disk storage, magnetic disk storage or other magnetic storage devices, or any other medium that may be used to carry or store desired program code in the form of instructions or data structures and that may be accessed by a computer.

Therefore, although selected aspects have been illustrated and described in detail, it will be understood that various substitutions and alterations may be made therein without departing from the spirit and scope of the present invention, as defined by the following claims.

What is claimed is:

1. A method for deep coalescing memory management in a portable computing device (“PCD”), the method comprising:
instantiating a first deep coalescing (“DC”) buffer in a cache memory, wherein the first DC buffer is uniquely associated with data transaction requests that are read requests from a particular multimedia (“MM”) client;
instantiating a second DC buffer in the cache memory, wherein the second DC buffer is uniquely associated with data transaction requests that are write requests from the MM client;
receiving a first data transaction request from the MM client;
determining that the first data transaction request is a write request; and
queuing the write request in the second DC buffer, wherein queuing the write request comprises sequentially ordering the write request relative to other write requests queued in the second DC buffer based on associated addresses in a double data rate (“DDR”) memory component.

2. The method of claim 1, further comprising:
receiving a second data transaction request from the MM client;
determining that the second data transaction request is a read request;
retrieving data from the first DC buffer based on the read request; and
returning the retrieved data to the MM client.

3. The method of claim 1, further comprising:
determining that the second DC buffer is eligible for flushing to the DDR memory component, wherein eligibility is based on a threshold amount of sequentially ordered data being queued in the second DC buffer; and
flushing at least a portion of the data queued in the second DC buffer to the DDR memory component, wherein flushing the data to the DDR component comprises updating data stored in the DDR component at sequential addresses of a memory page.

4. The method of claim 3, further comprising stalling the MM client until the second DC buffer is flushed to the DDR component.

5. The method of claim 1, further comprising:
determining that the first DC buffer is eligible for receiving data from the DDR memory component, wherein eligibility is based on a threshold amount of available capacity in the first DC buffer; and
retrieving a block of data from the DDR memory component and storing it in the first DC buffer, wherein retrieving the block of data from the DDR component comprises retrieving data stored at sequential addresses of a memory page.

6. The method of claim 1, wherein the size of the first and second DC buffers is based on a pattern of data transaction requests associated with the MM client.

7. The method of claim 1, wherein the PCD is in the form of a wireless telephone.

8. A system for deep coalescing memory management in a portable computing device (“PCD”), the system comprising:
means for instantiating a first deep coalescing (“DC”) buffer in a cache memory, wherein the first DC buffer is uniquely associated with data transaction requests that are read requests from a particular multimedia (“MM”) client;
means for instantiating a second DC buffer in the cache memory, wherein the second DC buffer is uniquely associated with data transaction requests that are write requests from the MM client;
means for receiving a first data transaction request from the MM client;
means for determining that the first data transaction request is a write request; and
means for queuing the write request in the second DC buffer, wherein queuing the write request comprises sequentially ordering the write request relative to other write requests queued in the second DC buffer based on associated addresses in a double data rate (“DDR”) memory component.

9. The system of claim 8, further comprising:
means for receiving a second data transaction request from the MM client;
means for determining that the second data transaction request is a read request;
means for retrieving data from the first DC buffer based on the read request; and
means for returning the retrieved data to the MM client.

10. The system of claim 8, further comprising:
means for determining that the second DC buffer is eligible for flushing to the DDR memory component, wherein eligibility is based on a threshold amount of sequentially ordered data being queued in the second DC buffer; and
means for flushing at least a portion of the data queued in the second DC buffer to the DDR memory component, wherein flushing the data to the DDR component comprises updating data stored in the DDR component at sequential addresses of a memory page.

11. The system of claim 10, further comprising means for stalling the MM client until the second DC buffer is flushed to the DDR component.

12. The system of claim 8, further comprising:
means for determining that the first DC buffer is eligible for receiving data from the DDR memory component, wherein eligibility is based on a threshold amount of available capacity in the first DC buffer; and
means for retrieving a block of data from the DDR memory component and storing it in the first DC buffer, wherein retrieving the block of data from the DDR component comprises retrieving data stored at sequential addresses of a memory page.

13. The system of claim 8, wherein the size of the first and second DC buffers is based on a pattern of data transaction requests associated with the MM client.

14. A system for deep coalescing memory management in a portable computing device (“PCD”), the system comprising:
a deep coalescing traffic (“DCT”) manager module configured to:
instantiate a first deep coalescing (“DC”) buffer in a cache memory, wherein the first DC buffer is uniquely associated with data transaction requests that are read requests from a particular multimedia (“MM”) client;
instantiate a second DC buffer in the cache memory, wherein the second DC buffer is uniquely associated with data transaction requests that are write requests from the MM client;
receive a first data transaction request from the MM client;
determine that the first data transaction request is a write request; and
queue the write request in the second DC buffer, wherein queuing the write request comprises sequentially ordering the write request relative to other write requests queued in the second DC buffer based on associated addresses in a double data rate (“DDR”) memory component.

15. The system of claim 14, wherein the DCT module is further configured to:
receive a second data transaction request from the MM client;
determine that the second data transaction request is a read request;
retrieve data from the first DC buffer based on the read request; and
return the retrieved data to the MM client.

16. The system of claim 14, wherein the DCT module is further configured to:
determine that the second DC buffer is eligible for flushing to the DDR memory component, wherein eligibility is based on a threshold amount of sequentially ordered data being queued in the second DC buffer; and
flush at least a portion of the data queued in the second DC buffer to the DDR memory component, wherein flushing the data to the DDR component comprises updating data stored in the DDR component at sequential addresses of a memory page.

17. The system of claim 16, wherein the DCT module is further configured to stall the MM client until the second DC buffer is flushed to the DDR component.

18. The system of claim 14, wherein the DCT module is further configured to:
determine that the first DC buffer is eligible for receiving data from the DDR memory component, wherein eligibility is based on a threshold amount of available capacity in the first DC buffer; and
retrieve a block of data from the DDR memory component and storing it in the first DC buffer, wherein retrieving the block of data from the DDR component comprises retrieving data stored at sequential addresses of a memory page.

19. The system of claim 14, wherein the size of the first and second DC buffers is based on a pattern of data transaction requests associated with the MM client.

20. The system of claim 14, wherein the PCD is in the form of a wireless telephone.
